(19) United States
(12) Patent Application Publication
(10) Pub. No.: US 2022/0283509 A1
(43) Pub. Date: Sep. 8, 2022

(54) SUPPORT OF AN OPTICAL UNIT

(71) Applicant: Carl Zeiss SMT GmbH, Oberkochen (DE)

(72) Inventors: Boaz Pnini, Goeggingen (DE); Jens Kugler, Aalen (DE); Bernhard Gellrich, Aalen (DE)

(21) Appl. No.: 17/664,278

(22) Filed: May 20, 2022

Related U.S. Application Data
(63) Continuation of application No. PCT/EP2020/083333, filed on Nov. 25, 2020.

(30) Foreign Application Priority Data
Nov. 29, 2019 (DE) 102019218609.2

(51) Int. Cl. G03F 7/20

(52) U.S. Cl. CPC G03F 7/70141; G03F 7/70825; G03F 7/70833; G03F 7/70975; G03F 7/7065

(57) ABSTRACT

An arrangement for use in a microlithographic optical imaging device includes an optical unit and a supporting structure for supporting the optical unit. The optical unit includes an optical element, a carrier structure for carrying the optical element, and an active actuating device. The optical element is supported on the carrier structure via of the active actuating device. The active actuating device is configured to adjust the optical element during normal operation of the optical imaging device in a maximum movement range, which is predefined by the normal operation of the optical imaging device, with respect to a first reference assigned to the imaging device. The active actuating device is configured so that the maximum movement range is completely covered by actuating movements of the active actuating device with an actuating accuracy predefined by the normal operation of the optical imaging device.

### CROSS-REFERENCE TO RELATED APPLICATIONS

The present application is a continuation of, and claims benefit under 35 USC 120 to, international application PCT/EP2020/083333, filed Nov. 25, 2020, which claims benefit under 35 USC 119 of German Application No. 10 2019 218 609.2, filed Nov. 29, 2019. The entire disclosure of these applications are incorporated by reference herein.

### FIELD

The present disclosure relates to a microlithographic arrangement including a supporting structure for supporting an optical unit which is suitable for the use of used UV light, for example in the extreme ultraviolet (EUV) range. Furthermore, the disclosure relates to an optical imaging device including such an arrangement, and to a corresponding method for supporting an optical unit. The disclosure can be used in conjunction with any desired optical imaging methods. It can be used in the production or the inspection of microelectronic circuits and the optical components used for them (for example optical masks).

### BACKGROUND

The optical devices used in conjunction with the production of microelectronic circuits typically included a plurality of optical element units including one or more optical elements, such as lens elements, mirrors or optical gratings, which are disposed in the imaging light path. The optical elements typically cooperate in an imaging process in order to transfer an image of an object (for example a pattern formed on a mask) to a substrate (for example a so-called wafer). The optical elements are typically combined in one or more functional groups, which are possibly held in separate imaging units. For example in the case of principally refractive systems that operate with a wavelength in the so-called vacuum ultraviolet range (VUV, for example at a wavelength of 193 nm), such imaging units are often formed from a stack of optical modules holding one or more optical elements. The optical modules typically include a supporting structure having a substantially ring-shaped outer supporting unit, which supports one or more optical element holders, which in turn hold the optical element.

The ever-advancing miniaturization of semiconductor components results in a constant demand for increased resolution of the optical systems used for their production. This demand for increased resolution can involve the demand for an increased numerical aperture (NA) and an increased imaging accuracy of the optical systems.

One approach for obtaining an increased optical resolution is to reduce the wavelength of the light used in the imaging process. The trend in recent years has increasingly fostered the development of systems in which light in the so-called extreme ultraviolet (EUV) range is used, typically at wavelengths of 5 nm to 20 nm, in most cases at a wavelength of approximately 13 nm. In this EUV range it is no longer possible to use conventional refractive optical systems. This is owing to the fact that in this EUV range the materials used for refractive optical systems have an absorbance that is too high to achieve acceptable imaging results with the available light power. Consequently, in this EUV range it is desirable to use reflective optical systems for the imaging.

This transition to purely reflective optical systems having a high numerical aperture (e.g. NA>0.4 to 0.5 and more) in the EUV range results in considerable challenges with regard to the design of the imaging device.

The factors mentioned above can result in very stringent desired properties with regard to the position and/or orientation of the optical elements participating in the imaging relative to one another and also with regard to the deformation of the individual optical elements in order to achieve a desired imaging accuracy. Moreover, it is desirable to maintain this high imaging accuracy over operation in its entirety, ultimately over the lifetime of the system.

As a consequence, the components of the optical imaging device (i.e., for example, the optical elements of the illumination device, the mask, the optical elements of the projection device and the substrate) which cooperate during the imaging are desirably supported in a well-defined manner in order to maintain a predetermined well-defined spatial relationship between these components and to obtain a minimal undesired deformation of these components in order ultimately to achieve the highest possible imaging quality.

For example with the aforementioned EUV systems, for system-related reasons, the illumination device and the projection device are typically relatively large and heavy optical units, which in newer systems can possibly reach a mass of 6 t to 8 t. The optical elements of these heavy units have to be adjustable during operation in order to comply with the accuracy properties described. In this case, besides the (usually dynamic) fine setting of the optical elements, for so-called setting changes of the imaging device, it may also be desirable to realize larger adjustment distances of the optical elements.

One such configuration is known for example from US 2011/0299053 A1 (Steinbach et al., the entire disclosure of which is incorporated by reference herein). In that case, the optical element is adjusted in a maximum movement range, which is predefined by the normal operation of the optical imaging device, in two stages by way of two separate actuating devices. In that case, one of the actuating devices brings about the coarse setting (e.g. for setting changes), while the other actuating device performs the fine setting.

A misalignment can occur on account of impacts or vibrations (such as can occur as a result of envisaged or unenvisaged events during transport or in the operating environment of the imaging device) especially in the case of large and heavy optical units, and the misalignment then typically has to be compensated for using the active actuating devices. This can result in the active actuating devices, for example the actuating device for the fine setting, besides the normal (typically dynamic) setting, also having to compensate for such a misalignment. For this purpose, the actuating device for the fine setting, which actuating device is designed for a high dynamic range and therefore involves a high outlay, can keep available an additional actuating travel or additional actuating capacity (over and above the actuating capacity involved anyway during normal operation). The outlay for the active actuating device and thus the imaging device increases considerably as a result.

### SUMMARY

The disclosure seeks to provide a microlithographic arrangement including a supporting structure for supporting an optical unit, a corresponding optical imaging device including such an arrangement, and a corresponding method for supporting an optical device which do not have the undesirable features mentioned above, or at least have them to a lesser extent, and markedly reduce the outlay and expense for the defined support of the optical unit for example in a simple manner.

The disclosure involves the technical teaching that in the case of the support of an optical unit, for example of a heavy optical unit, of the type mentioned in the introduction, the outlay for the support can be appreciably reduced if the active actuating device of the optical unit, which brings about the actuating movements of the optical element that are involved during normal operation, is configured only for the normal operation (that is to say for example covers substantially only the maximum movement space of the optical element that is involved during normal operation), while an additional separate adjustment device serves to adjust the optical unit as a whole in the already assembled state of the imaging device. The outlay and expense for the actuating device of the optical unit that is typically configured for a high dynamic range and therefore involves a high outlay can be considerably reduced as a result. Overall, the outlay for the imaging device can thereby be noticeably reduced despite the additional separate adjustment device.

The optical unit as a whole can be adjusted even in the already assembled state of the imaging device. In other words, the adjustment can then be effected even at an arbitrary later point in time after the delivery of the imaging device, for example regularly and/or after arbitrary events that might result in a misalignment (e.g. in the case of which unusually high shock loads, increased thermal loads, etc. have occurred). In this case, the adjustment can be effected for example without the optical unit or imaging-relevant components of the imaging device having to be demounted, which would otherwise entail a renewed adjustment of the demounted components.

The adjustment can be effected, in general, in as many degrees of freedom in space as possible through to all six degrees of freedom in space (in other words, N=1 to N=6 can thus hold true). The number of degrees of freedom that are adjustable by the adjustment device can depend for example on the number of degrees of freedom in which a misalignment has an appreciable influence on the predefined imaging quality of the imaging device. An adjustment in degrees of freedom in which a misalignment has no appreciable influence can therefore be obviated, if appropriate.

According to one aspect, the disclosure relates to an arrangement for use in a microlithographic optical imaging device, for example using light in the extreme UV (EUV) range, including an optical unit and a supporting structure for supporting the optical unit. The optical unit includes at least one optical element, a carrier structure for carrying the at least one optical element, and an active actuating device, wherein the optical element is supported on the carrier structure by way of the active actuating device. The active actuating device is configured to adjust the optical element during normal operation of the optical imaging device in a maximum movement range, which is predefined by the normal operation of the optical imaging device, with respect to a first reference assigned to the imaging device. Herein, the active actuating device is configured in such a way that the maximum movement range is completely covered by actuating movements of the active actuating device with an actuating accuracy predefined by the normal operation of the optical imaging device. The optical unit is supported on the supporting structure by way of an interface device of the supporting structure, wherein an adjustment device is provided, which for example is part of the interface device. The adjustment device is configured to adjust, in an assembled state of the optical imaging device, a position and/or orientation of a second reference assigned to the optical unit, for example to the optical element, with respect to the first reference in N degrees of freedom.

The second reference can be, in general, an arbitrary reference on the basis of which a sufficiently precise detection of a deviation of the optical unit, for example of the optical element, from a predefined spatial location (that is to say spatial position and/or orientation) can be detected. The reference can be, for example, a reference of the optical element. This can be the case, for example, if the spatial location of the optical element with respect to the carrier structure is sufficiently known, such that sufficiently precise conclusions about a possibly desired adjustment of the optical unit by way of the adjustment device can be drawn for example from a detected relationship between the first reference and the second reference. For this purpose, a corresponding detection device can be provided, for example, which detects this spatial location of the optical element (for example the spatial location of the reference of the optical element, which then also forms the second reference) with respect to the carrier structure.

In variants, the second reference is assigned to the carrier structure. It is thereby possible to detect the spatial location of the carrier structure with respect to the first reference and to carry out a corresponding correction by way of the adjustment device when a deviation from a target state is present.

In variants configured in a particularly simple manner, the second reference is a reference of the carrier structure. This can be realized, in general, in any desired suitable way. In this regard, the second reference can be a virtual reference, for example, which results or is calculated from one or more reference points on the carrier structure. For simple variants, the second reference is a component of the carrier structure. In this case, it can be desirable if the second reference is a measuring element arranged on the carrier structure. In general, any desired suitable measuring elements can be used in this case. For example, they can be any desired active or passive measuring elements that are arranged at a suitable place on the carrier structure. In the case of particularly simple passive variants, the measuring element is a simple measuring surface. This measuring surface can then be used in a simple manner for (tactile or non-contact) measurement. A non-contact measurement can be desirable, of course, in which for example a measurement light beam (or other electromagnetic radiation) impinges on the measuring surface and is correspondingly reflected and/or altered in a sufficiently known manner. In this case, for example, a correspondingly structured measuring area (for example having a one- or multidimensional grid) can be used in order thereby to obtain correspondingly additional information in a sufficiently well-known manner.

It goes without saying that the adjustment device can be arranged at any desired suitable place, in general, in order to perform the desired adjustment of the second reference with respect to the first reference. In this case, the adjustment device can act within the supporting structure, for example, that is to say that a correction (in all or some of the N degrees of freedom) can thus be carried out within the supporting structure. For simple variants, the adjustment device is arranged between the supporting structure and the carrier structure. In these cases, the adjustment device is then configured to adjust a position and/or orientation of the carrier structure in the N degrees of freedom.

In this case, the adjustment device can be configured in any desired way, in general, in order to bring about the adjustment in the N degrees of freedom. Individual degrees of freedom can be set in a combined manner using a common adjustment unit. It goes without saying, however, that in other variants a separate adjustment unit can also be provided for each of the N degrees of freedom. In certain variants, the adjustment device therefore includes at least one adjustment unit. It can be desirable for the adjustment device to include 1 to 6 adjustment units, such as 2 to 6 adjustment units, for example 3 to 4 adjustment units.

For their part, the adjustment units can in turn be configured in any desired suitable way. It can be desirable for the at least one adjustment unit to include at least one adjustment element for adjusting a position and/or orientation of the carrier structure in one of the N degrees of freedom. In this case, it can be desirable for the adjustment unit to be a passive adjustment unit, since a particularly simple and cost-effective configuration can be realized by this means. In general, any desired suitable passive actuating mechanisms can be used here. Particularly simple and robust configurations arise if the passive adjustment element is an adjustment screw. The same applies if, additionally or alternatively, the passive adjustment element is an exchangeable spacer element.

The active actuating device can provide, in general, an adjustment of the optical element in as many degrees of freedom as desired up to all six degrees of freedom in space. Accordingly, the active actuating device can be configured to adjust the optical element during normal operation in the maximum movement range in at most M degrees of freedom in space. In this case, M can equal to 1 to 6, such as to 2 to 5, for example 3 to 4. This makes it possible to achieve particularly expedient configurations with a correction of imaging aberrations.

It goes without saying that the N degrees of freedom in which an adjustment can be carried out by way of the adjustment device can in general correspond wholly or partly to the M degrees of freedom in which the active actuating device can adjust the optical element. As already mentioned, it can be provided that the adjustment device can carry out a setting in up to all six degrees of freedom in space. The number N can be equal to 1 to 6, such as 2 to 5, for example 3 to 4. This also makes it possible to achieve particularly expedient configurations with a correction or avoidance of imaging aberrations.

Likewise, it can also be provided, however, that a portion of the N degrees of freedom in which an adjustment can be carried out by way of the adjustment device in each case does not correspond to one of the M degrees of freedom which can be set using the active actuating device. For example, it can thus be provided that at least one of the N degrees of freedom in which the adjustment device acts is not encompassed by the M degrees of freedom in which the active actuating device acts. It is thereby possible, for example, to perform an adjustment in degrees of freedom which do not require dynamic correction by way of the active actuating device during operation. The active actuating device can accordingly disregard or not cover these degrees of freedom and, consequently, can be configured correspondingly more simply and more cost-effectively.

A deviation of the second reference from its target state (target position and/or target orientation) can in general be detected in any desired suitable way and then be used for adjustment using the adjustment device. For this purpose, the optical unit and/or the supporting structure can include at least one measuring element of a measuring device, wherein the measuring device is then configured, using the at least one measuring element, to detect a deviation of the second reference from a predefinable target position and/or target orientation of the second reference. It is thereby possible, in a particularly simple manner, to realize a corresponding detection of such a deviation and a subsequent adjustment.

In this case, the measuring element can be arranged at any desired suitable place, in general, in order to enable a correspondingly precise detection of such a deviation. The at least one measuring element can be arranged in the region of the interface device since a reliable and sufficiently precise detection is thereby possible in a particularly simple manner.

In this case, provision can be made, for example, for the at least one measuring element to be arranged in the region of a carrier structure interface surface of the carrier structure. This can be desirable for example because by this means it is also possible to detect alterations (for example settling or some other alteration of the connection) in the region of the interface device in a simple manner. In this case, it can be desirable, for example, if the at least one measuring element is arranged on the carrier structure interface surface of the carrier structure, wherein the interface device is connected to the carrier structure via the carrier structure interface surface.

Additionally or alternatively, it can be provided that the at least one measuring element is arranged in the region of a supporting structure interface surface of the supporting structure, for example is arranged on the supporting structure interface surface of the supporting structure, wherein the interface device is connected to a structure element of the supporting structure via the supporting structure interface surface. By this means, it is then possible to detect corresponding alterations at the supporting structure.

It goes without saying that for the measuring device, in general, any desired suitable and sufficiently known measurement principles can be used which make it possible to detect the relative location of the first and second references with sufficient accuracy. In variants, the at least one measuring element is a capacitive component of the measuring device that operates at least partly according to a capacitive principle of action. Additionally or alternatively, it can be provided that the at least one measuring element is an optically effective component of the measuring device that operates at least partly according to an optical principle of action.

It goes without saying that the deviation of the location of the first and second references from the target location thereof can be detected continuously or intermittently (at any desired suitable time intervals or as a reaction to specific events).

It furthermore goes without saying that a maximum permissible deviation of the second reference from the target position and/or target orientation of the second reference is predefined, and the measuring device is configured to trigger a predefinable reaction upon the maximum permissible deviation being exceeded. This can involve an active, fully or partly automatic adjustment process in the case of an active adjustment device. Likewise, simply just a corresponding indication signal can be output, for example, in the case of a passive adjustment device.

In certain variants, an event monitoring device is provided, wherein the event monitoring device is configured to detect the occurrence of events, for example accelerations, at the optical unit and/or the supporting structure, as the result of which a predefinable deviation of the second reference from a predefinable target position and/or target orientation of the second reference is to be expected. It is thereby possible, in a simple manner, to realize a situation-conforming and optionally early detection of the relative location between the first and second references.

The event monitoring device can be configured to generate an event signal upon one of the events occurring. The event signal can be configured and/or processed in any desired way, in general. For example, advantageous variants, the event monitoring device is configured to output the event signal to a measuring device, wherein the measuring device is then configured, in reaction to receiving the event signal, to detect a deviation of the second reference from a predefinable target position and/or target orientation of the second reference

In certain advantageous variants, the event monitoring device includes at least one event sensor, wherein the at least one event sensor is arranged on the optical unit and/or the supporting structure. It is thereby possible to realize a reliable detection of relevant events in a particularly simple manner.

The detection of such events can be effected in any desired suitable manner, in general. It is particularly advantageous if the at least one event sensor is an acceleration sensor. Additionally or alternatively, the at least one event sensor can be a force sensor. In both cases, events such as vibrations, for example, which can result in an alteration of the relative location between the first and second references, can be detected in a particularly simple manner.

The present disclosure furthermore relates to an optical imaging device, for example for microlithography, including an illumination device with a first optical element group, an object device for receiving an object, a projection device with a second optical element group and an image device. The illumination device is configured to illuminate the object, while the projection device is configured to project an image of the object onto the image device. The illumination device and/or the projection device include(s) at least one arrangement according to the present disclosure. This makes it possible to achieve the variants and advantages described above in connection with the arrangement according to the disclosure to the same extent, and so reference is made to the explanations given above in this respect.

The present disclosure furthermore relates to a method for supporting an optical unit of a microlithographic optical imaging device, for example using light in the extreme UV (EUV) range, via a supporting structure, wherein an optical element of the optical unit is supported on a carrier structure of the optical unit by way of an active actuating device of the optical unit. The active actuating device adjusts the optical element during normal operation of the optical imaging device in a maximum movement range, which is predefined by the normal operation of the optical imaging device, with respect to a first reference assigned to the imaging device. In this case, the maximum movement range is completely covered by actuating movements of the active actuating device with an actuating accuracy predefined by the normal operation of the optical imaging device. The optical unit is supported on the supporting structure by way of an interface device of the supporting structure, wherein in an assembled state of the optical imaging device, an adjustment device, for example an adjustment device of the interface device, adjusts a position and/or orientation of a second reference assigned to the optical unit, for example to the optical element, with respect to the first reference in N degrees of freedom. This again makes it possible to achieve the variants and advantages described above in connection with the arrangement according to the disclosure to the same extent, and so reference is made to the explanations given above in this respect.

Further aspects and exemplary embodiments of the disclosure are evident from the dependent claims and the following description of exemplary embodiments, which refers to the accompanying figures. All combinations of the disclosed features, irrespective of whether or not they are the subject of a claim, lie within the scope of protection of the disclosure.

### BRIEF DESCRIPTION OF THE DRAWINGS

FIG. 1 is a schematic illustration of an embodiment of a projection exposure apparatus according to the disclosure, which includes an embodiment of an arrangement according to the disclosure and with which embodiments of the methods according to the disclosure can be carried out.

FIG. 2 is a schematic illustration of the arrangement according to the disclosure from FIG. 1.

### DETAILED DESCRIPTION OF THE DISCLOSURE

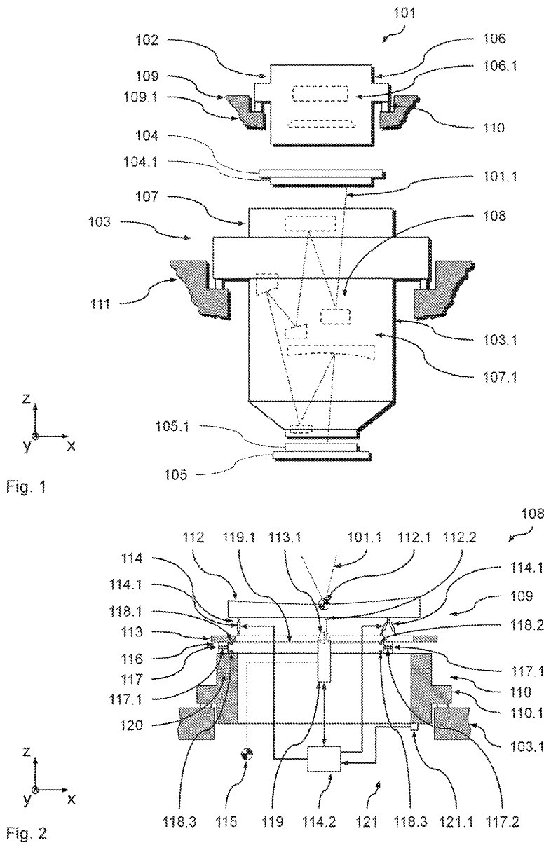

An exemplary embodiment of a microlithographic projection exposure apparatus 101 according to the disclosure, which includes an exemplary embodiment of an optical arrangement according to the disclosure, is described below with reference to FIGS. 1 and 2. To simplify the following explanations, an x,y,z coordinate system is indicated in the drawings, the z direction extending along the direction of the gravitational force. It goes without saying that it is possible in further configurations to choose any desired other orientations of an x,y,z coordinate system.

FIG. 1 is a schematic, not-to-scale illustration of the projection exposure apparatus 101, which is used in a microlithographic process for producing semiconductor components. The projection exposure apparatus 101 includes an illumination device 102 and a projection device 103. The projection device 103 is configured to transfer an image of a structure of a mask 104.1, which is disposed in a mask unit 104, onto a substrate 105.1, which is disposed in a substrate unit 105, in an exposure process. For this purpose, the illumination device 102 illuminates the mask 104.1. The optical projection device 103 receives the light from the mask 104.1 and projects the image of the mask structure of the mask 104.1 onto the substrate 105.1, such as for example a wafer or the like.

The illumination device 102 includes an optical device 106 with an optical element group 106.1. The projection device 103 includes a further optical device 107 with an optical element group 107.1. The optical element groups 106.1, 107.1 are disposed along a folded beam path 101.1 of the projection exposure apparatus 101. Each of the optical element groups 106.1, 107.1 can include a multiplicity of optical modules, which in turn each include one or more optical elements.

In the present exemplary embodiment, the projection exposure apparatus 101 operates with used light in the EUV range (extreme ultraviolet radiation), with wavelengths of between 5 nm and 20 nm, for example with a wavelength of 13 nm. The optical elements of the element groups 106.1, 107.1 of the illumination device 102 and the projection device 103 are therefore exclusively reflective optical elements. The optical units 106 and 107 can each include an embodiment of the optical arrangement according to the disclosure.

In further configurations of the disclosure, it is of course also possible (for example depending on the wavelength of the illumination light) to use any type of optical elements (refractive, reflective, diffractive) alone or in any desired combination for the other optical modules. Furthermore, the illumination device 102 and/or the projection device 103 can include one or more optical devices such as the optical device 106 and/or 107.

The optical arrangement according to the disclosure is described below in exemplary fashion on the basis of the optical arrangement 108 of the projection device 103. It goes without saying that the following explanations are also applicable to an arrangement of the illumination device 102. The latter can be configured for example identically to the optical arrangement 108 described below.

FIG. 2 shows a schematic illustration of the optical arrangement 108. The arrangement includes an optical unit 109 and a supporting structure 110 for supporting the optical unit 109. The supporting structure 110 is supported on a housing structure 103.1 of the projection device 103, which is in turn supported on a base structure 111.

In the present example, the optical unit 109 includes an optical element in the form of a mirror 112, a carrier structure 113 and an active actuating device 114, wherein the optical element 112 is supported on the carrier structure 113 by way of the active actuating device 114. The actuating device 114 is configured to adjust the optical element 112 during normal operation of the optical imaging device 101 in a maximum movement range MMR with respect to a first reference 115 (indicated schematically in FIG. 2) assigned to the imaging device 101. The maximum movement range MMR is predefined by the normal operation of the imaging device 101. The actuating device 114, with its actuating movements, completely covers the maximum movement range with an actuating accuracy that is predefined by the normal operation of the imaging device 101.

The active actuating device 114 can provide, in general, an adjustment of the optical element 112 in as many degrees of freedom as desired up to all six degrees of freedom in space. Accordingly, the active actuating device 114 can be configured to adjust the optical element during normal operation in the maximum movement range MMR in at most M degrees of freedom in space. M of degrees of freedom can equal to 1 to 6, such as 2 to 5, for example 3 to 4. It is thereby possible to achieve particularly expedient configurations with an advantageous correction of imaging aberrations of the imaging device 101.

For this purpose, the actuating device 114 can be configured in any desired suitable (and sufficiently known) manner, in general. In the present example, the actuating device 114 is configured as conventional hexapod kinematics, the actuating elements 114.1 of which are controlled by a corresponding control device 114.2, such that an adjustment in all six degrees of freedom in space is possible (that is to say that M=6 thus holds true).

The optical unit 109 is supported on the supporting structure 111 by way of an interface device 116 of the supporting structure 111. In this case, the interface device 116 includes an adjustment device 117, by which, in an assembled state of the imaging device 101, it is possible to adjust a position and/or orientation of a second reference 118.1, which is assigned to the optical unit 109, with respect to the first reference 115 in N degrees of freedom, as explained in even greater detail below.

By virtue of the additional adjustment device 117, it is possible to considerably reduce the outlay and expense for the support of the optical unit 109, particularly if the latter is a heavy optical unit 109. In this regard, the active actuating device 114 of the optical unit 109, which provides the actuating movements of the optical element that are involved for normal operation of the imaging device 101, can be configured only for this normal operation. The actuating device 114 then need cover substantially only the maximum movement space of the optical element 112 that is involved during normal operation, while the additional separate adjustment device 117 serves to adjust the optical unit 109 as a whole.

The adjustment device 117 makes it possible, for example, to compensate, in a simple manner and intermittently, for misalignment effects on the optical unit 109 which can arise over the time of use of the imaging device 101. The effects may involve for example so-called settling effects at the interfaces along the kinematic chain to the base structure 111. A deformation of the supporting structure along the kinematic chain may likewise be involved. The effects can develop slowly, that is to say thus be quasi-static. The effects may however likewise involve reactions of the structure to events taking place at certain points in time, for example impacts or the like. In all cases it is possible to perform a corresponding adjustment using the adjustment device 117 at an arbitrary time after the start-up of the imaging device 101. This can be done, for example, without the optical unit 109 or imaging-relevant components of the imaging device 101 having to be demounted.

With the adjustment device 117, the outlay and expense for the actuating device 114 of the optical unit 109, which is typically designed for a high dynamic range and is therefore configured with a high outlay, can be considerably reduced. Overall, the outlay and expense for the imaging device 101 can thereby be noticeably reduced despite the additional separate adjustment device 117.

In this case, the adjustment using the adjustment device 117 can be effected, in general, in as many degrees of freedom in space as possible up to all six degrees of freedom in space (in other words, N=1 to N=6 can thus hold true). In this case, the number of degrees of freedom that are adjustable by the adjustment device 117 can depend for example on the number of degrees of freedom in which a misalignment of the optical unit 109 has an appreciable influence on the predefined imaging quality of the imaging device 101. An adjustment in degrees of freedom in which a misalignment has no appreciable influence can therefore be obviated, if appropriate.

In the present example, the second reference 118.1 is assigned to the carrier structure 113 since it is thereby possible, in a particularly simple manner, to detect the spatial location of the carrier structure 113 with respect to the first reference 115 and to carry out a corresponding correction by way of the adjustment device 117 when a deviation from a target state is present.

A deviation of the second reference 118.1 from its target state (target position and/or target orientation with respect to the first reference 115) can in general be detected in any desired and suitable way and then be used for adjustment using the adjustment device 117.

In order to realize this, in the present example the second reference 118.1 is a component of the carrier structure 113. To put it more precisely, in the present example the second reference 118.1 is a measuring element arranged on the carrier structure 113. In general, any desired suitable measuring elements 118.1 can be used in this case. For example, they can be any desired active or passive measuring elements 118.1 that are arranged at a suitable place on the carrier structure 113.

In the present example, a simple passive variant is realized, in which the measuring element 118.1 is a simple measuring surface. In the present example, the measuring surface 118.1 is used for non-contact measurement by virtue of a measurement light beam 119.1 (or other electromagnetic radiation) of a measuring device 119 impinging on the measuring surface 118.1 and being correspondingly reflected and/or altered in a sufficiently known manner before it is picked up again by a suitable detector of the measuring device 119 in order to obtain information regarding the location of the measuring surface 118.1 with respect to the first reference 115 from the signal detected by the detector. In this case, optionally, a correspondingly structured measuring area 118.1 (for example having a one- or multidimensional grid) can be used in order thereby to obtain correspondingly additional information regarding the location of the measuring surface 118.1 with respect to the first reference 115 in a sufficiently known manner.

It goes without saying, however, that an active component can also be used in other variants for the second reference 118.1, which active component itself (in a sufficiently known manner) generates and emits a corresponding measurement signal, which then (if appropriate by this active component itself) is detected and processed further in order to obtain corresponding location information.

In the present example, therefore, the measuring device 119 is thus configured, using at least the measuring element 118.1, to detect a deviation of the second reference (which in the present example is formed by the measuring element 118.1 itself) from a predefinable target position and/or target orientation of the second reference. It is thereby possible, in a particularly simple manner, to realize a corresponding detection of such a deviation and a subsequent adjustment by the adjustment device 117.

As is indicated schematically by the dotted line 119.2 in FIG. 2, in the present example the measuring device 119 additionally detects the location of the first reference 115 with respect to the measuring device 119. It goes without saying, however, that other variants can lack such a detection, if the spatial relationship between the measuring device 119 and the first reference 115 is known with sufficient accuracy. This may be the case, for example, if the measuring device 119 is secured to a structure which also forms the first reference 115 and is subjected only to correspondingly small alterations (for example deformations) during operation. It may likewise be the case, of course, that a part of the measuring device 119 itself forms the first reference 115.

The measuring device 119 is a sufficiently known measuring device (which is therefore not described in greater detail below) which can be used to determine the spatial location of different components of the imaging device 101 with respect to one another. For this purpose, the measuring device 119 is supported in a defined way in any desired and sufficiently known manner (not illustrated in FIG. 2) and is configured to detect the spatial location of the components in any desired suitable manner, typically in a non-contact manner.

It furthermore goes without saying that, in other variants, the second reference (instead of the measuring element 118.1) can in general also be any desired other reference on the basis of which a sufficiently precise detection of a deviation of the optical unit 109, for example of the optical element 112, from a predefined spatial location (that is to say spatial position and/or orientation) with respect to the first reference 115 can be detected.

In certain variants, the second reference can also be a reference 112.1 (indicated schematically in FIG. 2) of the optical element 112. This can be the case for example if the spatial location of the optical element 112 with respect to the carrier structure 113 is sufficiently known, such that sufficiently precise conclusions about a possibly desired adjustment of the optical unit 109 by way of the adjustment device 117 can be drawn for example from a detected relationship between the first reference 115 and the reference 112.1. For this purpose, using the measuring device 119, a corresponding detection device can be provided, for example, which detects this spatial location of the optical element 112 (for example the spatial location of the reference 112.1 of the optical element, which then also forms the second reference) with respect to the carrier structure 113. This can be done, for example, by the measuring device 119 carrying out a corresponding measurement which makes use of the measuring element 118.1 on the carrier structure and a further measuring element 112.2 on the optical element 112.

Furthermore, it goes without saying that, in other variants, the second reference can for example also be a virtual reference of the carrier structure 113, as is indicated by the dashed contour 113.1 in FIG. 2. This virtual reference 113.1 can be ascertained for example on the basis of a plurality of reference points on the carrier structure 113. By way of example, a plurality of measuring elements arranged on the carrier structure 113 can be used for this purpose. By way of example, it is possible to use the measuring element 118.1 and one or more identical measuring elements 118.2 on the carrier structure 113 in order to ascertain the spatial location of the virtual reference 113.1 using the measuring device 119.

Likewise, in addition or as an alternative (to the measuring elements 118.1, 118.2), it is also possible, however, to use one or more measuring elements 118.3 (optionally constructed identically to the measuring element 118.1) on the supporting structure 110 in order to detect the spatial location of such a second reference with respect to the first reference 115 using the measuring device 119. One of the measuring elements 118.3 can then in turn form the second reference in a similar manner. Likewise, with the aid of one or more of these measuring elements 118.3, the spatial location of a virtual second reference can be determined in turn (analogously to the way described above in association with the measuring elements 118.1, 118.2).

In cases in which both the measuring elements 118.1, 118.2 and the measuring elements 118.3 find application, it is also possible, of course, to detect a deviation of the spatial location between the supporting structure 110 and the carrier structure 113 from a predefined target state and to take it into account accordingly in the adjustment.

It goes without saying that the measuring elements 118.1 to 118.3 can be arranged, in general, at any desired suitable place in order to enable a correspondingly precise detection of a deviation of the respective second reference from its target state. In the present example, the measuring elements 118.1, 118.2 and/or 118.3 are arranged in the region of the interface device 116 since a reliable and sufficiently precise detection is thereby possible in a particularly simple manner.

In this case, the relevant measuring element 118.1, 118.2 is arranged in each case in the region of a carrier structure interface surface of the carrier structure 113. This is advantageous for example because by this means it is also possible to detect alterations (for example settling or some other alteration of the connection) in the region of the interface device 116 in a simple manner. In this case, it can be advantageous, for example, if the measuring element 118.1 and/or 118.2 is arranged directly on the carrier structure interface surface of the carrier structure 113, the interface device 116 being connected to the carrier structure 113 via the carrier structure interface surface.

Additionally or alternatively, it can be provided that the measuring element(s) 118.3 are arranged in the region of a supporting structure interface surface of the supporting structure 110, for example are arranged directly on the supporting structure interface surface of the supporting structure, the interface device 116 being connected to a structure element 110.1 of the supporting structure 110 via the supporting structure interface surface. By this means, it is then possible to detect corresponding alterations at the supporting structure 110.

In the present example, the adjustment device 117 is arranged between the supporting structure 110 and the carrier structure 113. The adjustment device 117 is configured to adjust a position and/or orientation of the carrier structure 113 in the desired N degrees of freedom. In the present example, this is done by way of a plurality of adjustment units 117.1 of the adjustment device 117 that are arranged in a manner distributed on the periphery of the carrier structure 113. It goes without saying, however, that depending on the number (N) of degrees of freedom in which an adjustment is desired, if appropriate a single adjustment unit 117 may also be sufficient (particularly if for example only an adjustment in a single degree of freedom of rotation is desired).

It furthermore goes without saying that the adjustment device can in general also be arranged at any other suitable location in order to perform the desired adjustment of the second reference 118.1 with respect to the first reference 115. In this case, the adjustment device can act within the supporting structure 110, for example, that is to say that a correction (in all or some of the N degrees of freedom) can thus be carried out within the supporting structure 110, as is indicated by the dashed contour 120 in FIG. 2.

The adjustment device 117 can be configured in any desired way, in general, in order to bring about the adjustment in the N degrees of freedom. In this case, individual degrees of freedom can be set in a combined manner using a common adjustment unit 117.1. It goes without saying, however, that in other variants a separate adjustment unit 117.1 can also be provided for each of the N degrees of freedom. Consequently, six adjustment units 117.1 can thus optionally be provided. It is particularly advantageous if the adjustment device 117 includes 1 to 6 adjustment units 117.1. 2 to 6 adjustment units 117.1 can be provided. 3 to 4 adjustment units 117.1 can be provided.

For their part, the adjustment units 117.1 can in turn be configured in any desired suitable way. It is particularly advantageous if the respective adjustment unit 117.1 includes at least one adjustment element 117.2 for adjusting a position and/or orientation of the carrier structure 113 in one of the N degrees of freedom (as is explicitly illustrated only for one of the adjustment units 117.1 in FIG. 2, for reasons of clarity).

In this case, it is advantageous if the adjustment unit 117.1 is a passive adjustment unit, as in the present example, since a particularly simple and cost-effective configuration can be realized by this means. In general, any desired suitable passive actuating mechanisms can be used here. Particularly simple and robust configurations arise if the passive adjustment element 117.2 is an adjustment screw. The same applies if, additionally or alternatively, the passive adjustment element 117.2 is an exchangeable spacer element.

It goes without saying that the N degrees of freedom in which an adjustment can be carried out by way of the adjustment device 117 can in general correspond wholly or partly to the M degrees of freedom in which the active actuating device 114 can adjust the optical element 112. As already mentioned, it can be provided that the adjustment device 117 can carry out a setting in up to all six degrees of freedom in space. N can equal to 1 to 6, such as 2 to 5, for example 3 to 4.

Likewise, it can also be provided, however, that a portion of the N degrees of freedom in which an adjustment can be carried out by way of the adjustment device 117 in each case does not correspond to one of the M degrees of freedom which can be set using the active actuating device 114. For example, it can thus be provided that at least one of the N degrees of freedom in which the adjustment device 117 acts is not encompassed by the M degrees of freedom in which the active actuating device 114 acts. It is thereby possible, for example, to perform an adjustment in degrees of freedom which do not require dynamic correction by way of the active actuating device 114 during operation. The active actuating device 114 can accordingly disregard or not cover these degrees of freedom and, consequently, can be configured correspondingly more simply and more cost-effectively.

As has already been explained, it goes without saying that for the measuring device 119 any desired suitable and sufficiently known measurement principles can be used, in general, which make it possible to detect the relative location of the first reference 115 and second reference (118.1 and/or 112.1 and/or 113.1) with sufficient accuracy. In the present example, the respective measuring element 118.1, 118.2, 118.3, as described, is in each case an optically effective component of the measuring device 119 that operates according to an optical principle of action. In other variants, however, at least one of the measuring elements 118.1, 118.2, 118.3 can also be a capacitive component of the measuring device that then operates at least partly according to a capacitive principle of action.

It goes without saying that the deviation of the location of the first reference 115 and second reference (118.1 and/or 112.1 and/or 113.1) from the target location thereof can be detected continuously or intermittently (at any desired suitable time intervals or as a reaction to specific events).

It furthermore goes without saying that a maximum permissible deviation MPD of the second reference (118.1 and/or 112.1 and/or 113.1) from the target position and/or target orientation of the second reference can be predefined, and the measuring device 119 can be configured to trigger a predefinable reaction upon the maximum permissible deviation MPD being exceeded. The reaction can be an active, fully or partly automatic adjustment process in the case of an active adjustment device 117. Likewise, in the case of a passive adjustment device 117 such as is present in the present example, simply only a corresponding indication signal can be output on the part of the control device 114.2, which is connected to the measuring device 119 and performs the signal processing of the signals MS of the measuring device 119 in the present example. It goes without saying, however, that in other variants the measuring device 119 itself can also perform corresponding signal processing.

In the present example, an event monitoring device 121 is furthermore provided, which is formed by the control device 114.2 and, connected thereto, an event sensor in the form of an acceleration sensor 121.1. Additionally or alternatively, however, the event sensor 121.1 can also be formed by a force sensor. The event monitoring device 121 is configured to detect the occurrence of events, for example accelerations, at the supporting structure 110, as the result of which a predefinable deviation of the second reference (118.1 and/or 112.1 and/or 113.1) from its predefinable target position and/or target orientation with respect to the first reference 115 is to be expected. This makes it possible, in a simple manner, to realize an early and/or situation-conforming detection of the relative location between the first reference 115 and second reference (118.1 and/or 112.1 and/or 113.1).

In the present example, the event monitoring device 121 generates an event signal ES when one of the events mentioned above occurs, that is to say therefore when an acceleration above a specific limit value is detected. The event signal ES can be configured and/or processed in any desired way, in general. In the present example, the event monitoring device 121 outputs the event signal ES to the measuring device 119. In reaction to receiving the event signal ES, in the manner described above, the measuring device 119 then detects a possible deviation of the second reference (118.1 and/or 112.1 and/or 113.1) from its predefinable target position and/or target orientation with respect to the first reference 115.

The design described above makes it possible to realize, during operation of the imaging device 101, a corresponding embodiment of the method according to the disclosure for supporting the optical unit 106, which can be used both during the assembly of the imaging device 101 and during the operation of the imaging device 101. The individual method steps are evident here from the above description, and so reference is made to the explanations given above in this respect. For example, it is possible, in the manner described above, from time to time to carry out a corresponding adjustment of the optical unit 108 by way of the adjustment device 117 in order to ensure the desired imaging quality of the imaging device 101 in a simple manner.

The present disclosure has been described above exclusively on the basis of examples from the area of microlithography. However, it is understood that the disclosure can also be used in the context of any other optical applications, for example imaging methods at different wavelengths, in which similar problems arise in respect of the support of heavy optical units.

Furthermore, the disclosure can be used in connection with the inspection of objects, such as for example so-called mask inspection, in which the masks used for microlithography are inspected for their integrity, etc. In FIG. 1, a sensor unit, for example, which detects the imaging of the projection pattern of the mask 104.1 (for further processing), then takes the place of the substrate 105.1. This mask inspection can then take place substantially at the same wavelength as is used in the later microlithographic process. However, it is similarly possible also to use any desired wavelengths deviating therefrom for the inspection.

Finally, the present disclosure has been described above on the basis of specific exemplary embodiments showing specific combinations of the features defined in the following patent claims. It should expressly be pointed out at this juncture that the subject matter of the present disclosure is not restricted to these combinations of features, rather all other combinations of features such as are evident from the following patent claims also belong to the subject matter of the present disclosure.

What is claimed is:

1. An arrangement for use in a microlithographic optical imaging device, the arrangement comprising:
an optical unit, comprising:
an optical element;
a carrier structure carrying the optical element; and
an active actuating device;
a supporting structure, comprising:
an interface device supporting the optical unit; and
an adjustment device,
wherein:
the optical element is supported on the carrier structure via the active actuating device;
the active actuating device is configured to adjust the optical element during normal operation of the optical imaging device in a maximum movement range, which is based on normal operation of the optical imaging device, with respect to a first reference assigned to the imaging device;
the active actuating device is configured so that the maximum movement range is completely covered by actuating movements of the active actuating device with an actuating accuracy defined by the normal operation of the optical imaging device;
the adjustment device is configured to adjust, in an assembled state of the optical imaging device, a position and/or orientation of a second reference assigned to the optical unit with respect to the first reference in N degrees of freedom.

2. The arrangement of claim 1, wherein the interface device comprises the adjustment device.

3. The arrangement of claim 1, wherein the second reference is assigned to the optical element.

4. The arrangement of claim 1, wherein the second reference is assigned to the carrier structure.

5. The arrangement of claim 4, wherein the second reference is a component of the carrier structure.

6. The arrangement of claim 1, wherein:
the adjustment device is between the supporting structure and the carrier structure; and
the adjustment device is configured to adjust a position and/or orientation of the carrier structure in the N degrees of freedom.

7. The arrangement of claim 1, wherein the adjustment device comprises at least one adjustment unit.

8. The arrangement of claim 7, wherein the adjustment unit comprises a passive adjustment unit.

9. The arrangement of claim 1, wherein the active actuating device is configured to adjust the optical element during normal operation in the maximum movement range in at most M degrees of freedom in space, and at least one of the N degrees of freedom in which the adjustment device acts is not encompassed by the M degrees of freedom in which the active actuating device acts.

10. The arrangement of claim 1, wherein:
the optical unit and/or the supporting structure comprises a measuring element of a measuring device; and
the measuring device is configured, via the measuring element, to detect a deviation of the second reference from a predefinable target position and/or target orientation of the second reference.

11. The arrangement of claim 10, wherein the measuring element is in a region of the interface device.

12. The arrangement of claim 10, wherein the measuring element comprises a capacitive component of the measuring device configured to operate at least partly according to a capacitive principle of action.

13. The arrangement of claim 10, wherein the measuring device is configured to output an indication signal when a maximum permissible deviation of the second reference from the target position and/or target orientation of the second reference is exceeded.

14. The arrangement of claim 1, further comprising an event monitoring device configured to detect an occurrence of events at the optical unit and/or the supporting structure as a result of which a deviation of the second reference from a target position and/or target orientation of the second reference is expected.

15. The arrangement of claim 14, wherein the event monitoring device is configured to generate an event signal when one of the events occurs.

16. The arrangement of claim 14, wherein the event monitoring device comprises an event sensor on the optical unit and/or the supporting structure.

17. An optical imaging device, comprising:
an illumination device configured to illuminate an object in an object plane; and
a projection device configured to project an image of the object in the object plane into an image plane,
wherein the optical imaging device comprises a microlithography optical imaging device, and the illumination device comprises the arrangement of claim 1.

18. An optical imaging device, comprising:
an illumination device configured to illuminate an object in an object plane; and
a projection device configured to project an image of the object in the object plane into an image plane,
wherein the optical imaging device comprises a microlithography optical imaging device, and the projection device comprises the arrangement of claim 1.

19. A method for supporting an optical unit of a microlithographic optical imaging device, the method comprising:
using an active actuating device of an optical unit of the optical imaging device to support an optical element of the optical unit on a carrier structure;
using the active actuating device to adjust the optical element during normal operation of the optical imaging device in a maximum movement range, which is defined by the normal operation of the optical imaging device, with respect to a first reference assigned to the imaging device, the maximum movement range being completely covered by actuating movements of the active actuating device with an actuating accuracy defined by the normal operation of the optical imaging device;
using an interface device of a supporting structure of the optical unit to support the optical unit on the supporting structure; and
in an assembled state of the optical imaging device, using an adjustment device of the optical unit to adjust a position and/or orientation of a second reference assigned to the optical unit with respect to the first reference in N degrees of freedom.

20. The method of claim 1, wherein the active actuating device adjusts the optical element during normal operation in the maximum movement range in at most M degrees of freedom in space, and at least one of the N degrees of freedom in which the adjustment device acts is not encompassed by the M degrees of freedom in which the active actuating device acts.
